(19) United States
(12) Patent Application Publication
(10) Pub. No.: US 2005/0242858 A1
(43) Pub. Date: Nov. 3, 2005

(54) Apparatus and method for synchronized distributed pulse width modulation waveforms in microprocessor and digital signal processing devices

(76) Inventors: David A. Figoli, Missouri City, TX (US); Alexander Tessarolo, Lindfield NSW (AU)

Correspondence Address: TEXAS INSTRUMENTS INCORPORATED, P O BOX 655474, M/S 3999, DALLAS, TX, 75265, US

(21) Appl. No.: 11/107,232

(22) Filed: Apr. 15, 2005

Related U.S. Application Data
(60) Provisional application No. 60/563,718, filed on Apr. 20, 2004.

(51) Int. Cl. H03K 3/017

(52) U.S. Cl. 327/175

(57) ABSTRACT

A pulse width modulation module provides a first pulse width modulation signal and a second pulse width modulation signal, the two pulse width modulation signals having the same period, but different duty cycles. Each pulse width modulation module can be programmed to be reset by an external signal and can provide a programmable-selectable reset signal. The possible reset signals provided by the pulse width modulation module can be a signal externally applied to the pulse width modulation module, the reset signal for the first pulse signal modulation signal, and the set signal for the second pulse width modulation signal. In this manner, a pulse width modulation module can act as master or as slave modules, the pulse width modulation signal of the slave module having a selected relationship with the pulse width modulation signals of the master module.

This application claims priority under 35 USC §119 (e) (1) of Provisional Application No. 60/563,718 (TI-38294PS) filed Apr. 20, 2004.

### BACKGROUND OF THE INVENTION

1. Field of the Invention

This invention relates generally to data processing systems and, more particularly, to pulse width modulation devices frequently used in local power supply applications.

2. Background of the Invention

Pulse width modulation devices are widely used in microprocessors and in digital signal processing devices as local power supply devices. Referring to FIG. 1, a block diagram of pulse width modulation device 10 according to the prior art is shown. The system clock signals are applied to a clock terminal of counter 11. The output signal of the counter 11 is applied to a first input terminal of digital comparator 14 and to the first input terminal 15. An output signal from a period register 13 is applied to a second input terminal of digital comparator 14. An output signal from a compare register 12 is applied to a second input terminal of digital comparator 15. An output terminal of digital comparator 14 is applied to a reset terminal of counter 11 and to the clear terminal of Q flip flop 15. The output terminal of digital comparator 15 is applied to the set terminal of Q flip flop 16. The output signal of the Q flip flop is the PWM signal.

The operation of the prior art pulse width modulation device shown in FIG. 1 can be understood by reference to FIG. 2. After a reset operation in which the output of counter 11 is set to logic “0” and the output signal of the Q flip flop 16 is 0 voltage level in response to a CLEAR signal applied to the clear terminal. When the output signal of counter 11 is equal to the value stored in the compare register, a SET signal is applied to the set terminal of the Q flip flop. The output signal of the Q flip flop changes from a 0 voltage level to a positive voltage level. This positive voltage level continues until the count in the counter 11 equals the number stored in the period register 13. When the count in counter 11 equals the number stored in the period register, the digital comparator 14 generates a RESET signal. The RESET signal is applied to the rest terminal of counter 11 and to the clear terminal of Q flip flop 16. The RESET signal causes the count in counter 11 to reset to 0 and the output voltage of the Q flip flop to return to the 0 voltage. At this point, the operation then repeats.

The pulse width modulation (PWM) devices have frequent application in integrated circuits to providing local power sources, in the driving of multiphase motor, DC/DC converters. In the past, these PWM devices have designed and added to an integrated circuit in response to a specific application.

A need has therefore been felt for apparatus and an associated method having the feature of providing modular design for a PWM device that can used to provide PWM signals for powering selected components in a wide variety of applications. It would be a further feature of the apparatus and associated method to provide a PWM module that generates two PWM signals having the same period, but different duty cycles. It would be a still further feature of the apparatus and associated method to permit the PWM module to programmabley reset by an external signal. It would be yet another feature of the apparatus and associated method to provide a PWM module that can operate in a master mode and in a slave mode. It would be a still further feature of the apparatus and associated method to provide a slave module that is programmably synchronized with an associated master module.

### SUMMARY OF THE INVENTION

The foregoing and other features are accomplished, according the present invention, by providing a PWM module that provides a first PWM signal and a second PWM signal, the two PWM having the same period but different duty cycles. Each PWM module can be programmed to be reset by an external signal and can provide a programmably-selectable reset signal. The possible reset signals provided by the PWM module can be a signal externally applied to the PWM module, the reset signal for the first PWM signal, and the set signal for the second PWM signal. In this manner, a PWM module can act as master or as a slave module, the PWM of the slave module having a selected relationship with the PWM signals of the master module. The operation of the invention is described with respect to several applications.

Other features and advantages of present invention will be more clearly understood upon reading of the following description and the accompanying drawings and the claims.

### BRIEF DESCRIPTION OF THE DRAWINGS

FIG. 1 is block diagram showing an implementation of the pulse width modulation generator according to the prior art.

FIG. 2 illustrates the waveforms for the pulse width modulation generator of FIG. 1.

FIG. 3 is a pulse width modulation generator according to the present invention.

FIG. 4 illustrates the wave forms associated with the pulse width modulation generator of FIG. 3.

FIG. 5 is simplified representation of the pulse width modulation module shown in FIG. 3.

FIG. 6 is diagram of the “master” and “slave” configuration using the simplified representation of a pulse width modulation module according to the present invention.

FIG. 7 illustrates 6 modules, described by the present invention, coupled in chain.

FIG. 8 illustrates the application of the PWM modules of the present invention to control four independent Buck Stages.

FIG. 9 illustrates the application of the PWM modules of the present invention to control four Buck stages wherein the frequency of two of the Buck stages wherein the frequency of one pair of Buck stages is equal to an integer times the frequency of the second pair of Buck stages.

FIG. 10 illustrates the application of the PWM modules of the present invention to control of 2 Half-H bridge stages.

FIG. 11 illustrates the application of the PWM modules of the present invention to control of a Full-H bridge stage.

FIG. 12 illustrates the application of the PWM modules of the present invention to the control of two independent 3-phase motor inverters.

FIG. 13 illustrates how the PWM modules of the present invention can be used for phase control.

FIG. 14 provides a comparison of waveforms generated by the PWM configuration shown in FIG. 13.

FIG. 15 illustrates the use of the PWM modules of the present invention to provide power to a multiphase interleaved DC/DC converter requiring fixed phase offset between each 'A, 'B legs.

### DESCRIPTION OF THE PREFERRED EMBODIMENT

1. Detailed Description of the Figures

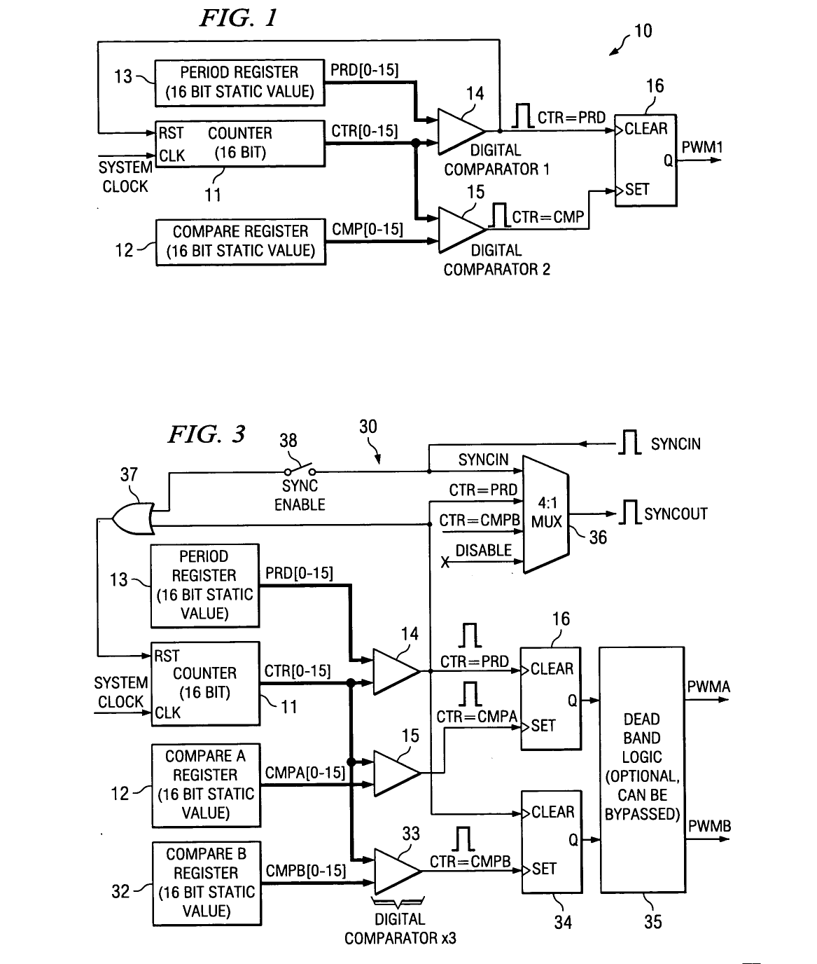

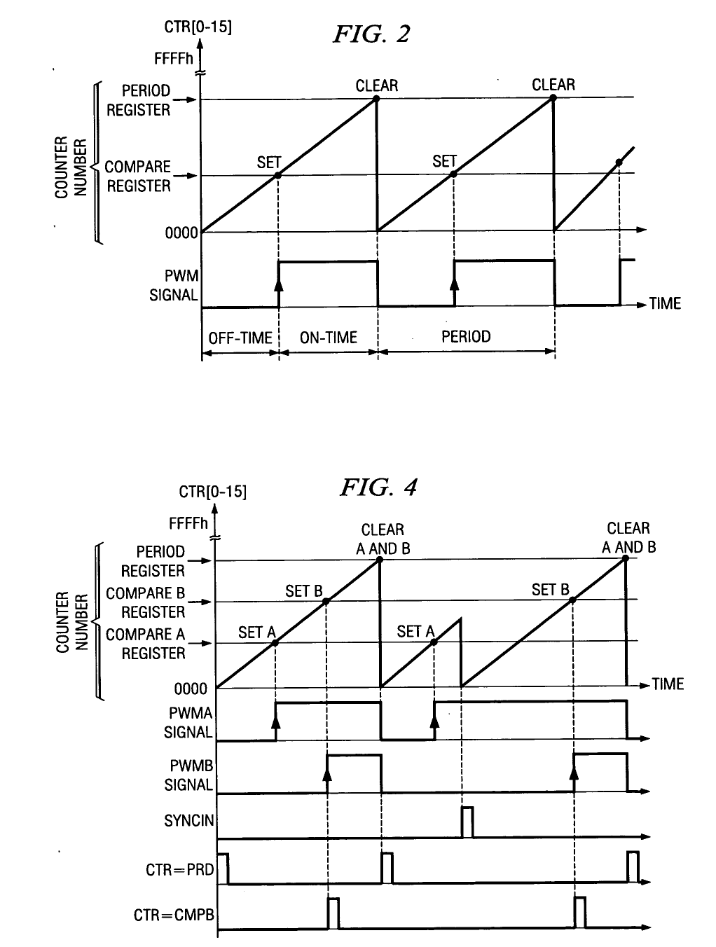

FIG. 1 and FIG. 2 have been described with respect to the prior art.

Referring next to FIG. 3, the pulse width modulation generator 30 according to the present invention is shown. The pulse width modulation generator 30 includes counter 11 for having SYSTEM CLOCK signals applied to the clock terminal, a periodic register 13, a compare register 12, an digital comparator 14, an digital comparator 15 and a Q flip flop coupled in a manner similar to that shown in FIG. 1. In addition to the components shown in FIG. 1, a compare B register 32 applies a count to a first terminal of digital comparator 33 while the output signal of counter 11 is applied to a second input terminal of digital comparator 33. The output signal of digital comparator 33 is applied to set terminal of Q flip flop 34, while the output signal of digital comparator 14 is applied to the clear terminal of Q flip flop 34. The output signal of Q flip flop is applied to a first terminal dead band logic 35 and, after processing, is the PWMA signal. The output signal of the Q flip flop 34 is applied to a second input terminal of dead band logic 35 and, after processing, provides the PWMB signal. The output signal of the digital comparator 14, instead of being applied to the reset terminal of counter 11, is applied to a first input terminal of logic “OR” gate 37 and to a first input terminal of multiplexer 35. A SYNCLN signal is applied to through a sync enable switch to a second input terminal of logic “OR” gate 37 and to a second input terminal of multiplexer 36. A third input terminal of multiplexer 36 has the output signal of digital comparator, while a fourth input terminal of multiplexer 36 has a DISABLE signal applied thereto. The output terminal of multiplexer 36 is the SYNCOUT signal.

The operation of the pulse width modulation generator can be understood with reference to FIG. 4. A first and a second pulse width modulation signal, PMWA and PMWB, having independent duty cycles but having the same periodicity (time-base) are each generated in the same manner as the single PWM signal in FIG. 1. Each PWM signal has duty cycle determined by the number stored in the associated compare register. A SYNCLN signal can be used to synchronize the counter to zero by means of the sync enable switch. FIG. 4 illustrates the effect of a SYNCLN signal in reinitializing the counter 11 independently of the set points derived from the number in the compare registers. A “flow through” mode is provided wherein a SYNCOUT signal is provided by the multiplexer 36. A module can be configured to be a “master” (i.e., generate a SYNC signal or a “slave”) (i.e., accepts the SYNC signal). The SYNCOUT signal can be configured to select from 4 synchronization options by means of the multiplexer 36. The entire module shown in FIG. 3 can operate independently with a time-base frequency different from the other modules.

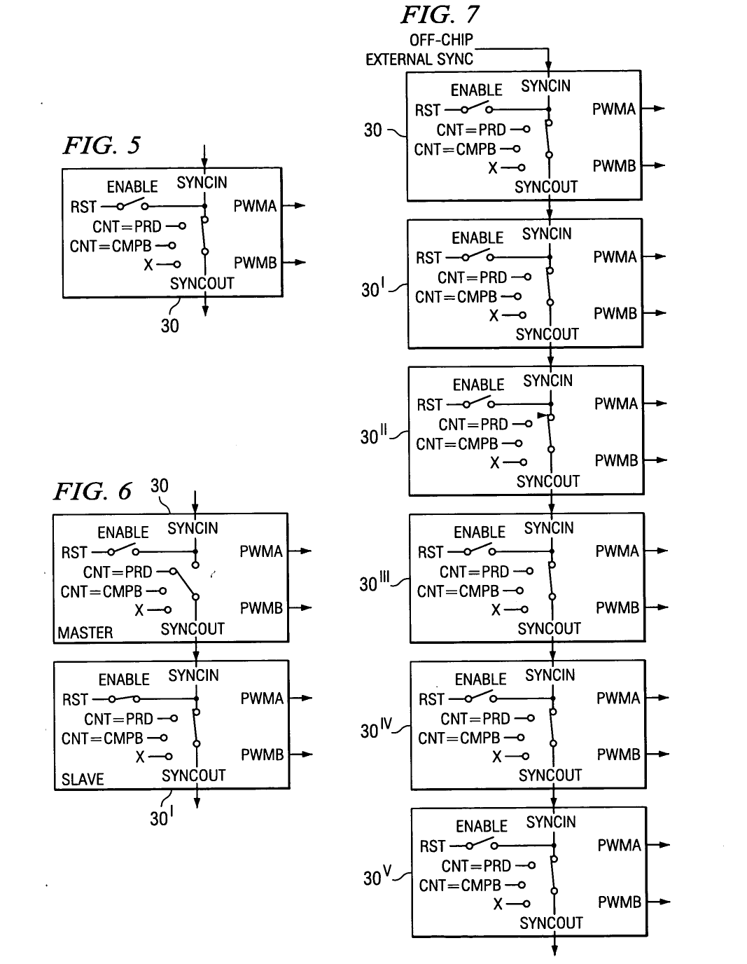

Referring to FIG. 5, a simplified representation of the module shown in FIG. 1 is illustrated. Using this representation, configuration choices available to each module can be illustrated. For the SYNCLN signal, the following choices are available:
1. Reset (synchronize) the time base from the incoming SYNC signal, the sync enable switch being closed; and
2. Do nothing, i.e., the sync enable switch being open.

For the SYNCOUT signal the configuration choices are:
1. SYNC signal “flow through”, the SYNCOUT signal being connected to the SYNCLN signal;
2. The module is the “master” and provides a SYNC signal at the PWM boundaries, the SYNCOUT signal being applied to the CNT signal=PRD signal.
3. The module is “master” and provides a SYNC signal at any programmable point in time, the SYNCOUT signal being connected to CNT signal=CMPB signal; and
4. Module is in a stand-alone mode and provides no SYNC signal to other modules, the SYNCOUT signal being connected to X (disabled).

For each choice of SYNCOUT signal configurations, a module may also be configured either to reset itself or not reset itself from the SYNC signal, i.e., by means of the sync enable switch. Although various combinations are possible, the two most common modes “master” module and “slave” module are illustrated in FIG. 6, using the simplified representation. In FIG. 6, the “slave” is synchronized with the CNT=PRD, i.e., when the number in the counter 11 is equal to the number in the period register.

Referring to FIG. 7, a configuration with a “daisy-chain” of six modules is shown. The module illustrated in FIG. 3 is meant to be integrated on a silicon chip along with a microprocessor of digital signal processor core, along with any associated apparatus (such a memory, communications, I/O, etc.) needed to support the system. While any number of modules can be used, six modules is typically sufficient for most applications. Since the modules are identical, the electrical coupling between them is fixed. This feature makes designing scalable systems simple.

Referring to FIG. 8, the use of two modules as described by the present invention to control 4 Buck stages is illustrated. Each Buck stage includes an FET transistor 81 having the control terminal coupled to a PWM output signal. One terminal of the FET transistor 81 is coupled to A Vin. The second terminal of the FET transistor 81 is coupled to the cathode of diode 82 and through the diode 3 to ground potential, is coupled through inductor 83 to a first terminal of capacitor 84 and is coupled through inductor to the Vout terminal. The second terminal of the capacitor 84 is coupled to ground potential. In the configuration shown in FIG. 8, a PWM module in the master mode provides PWM1A and PWM1B to the first two Buck stages and a second PWM module in the “master” mode provides the PWM2A and PWM2B signals to the third and fourth Buck stages. In this configuration, the two PWM modules operate independently and no synchronization is used.

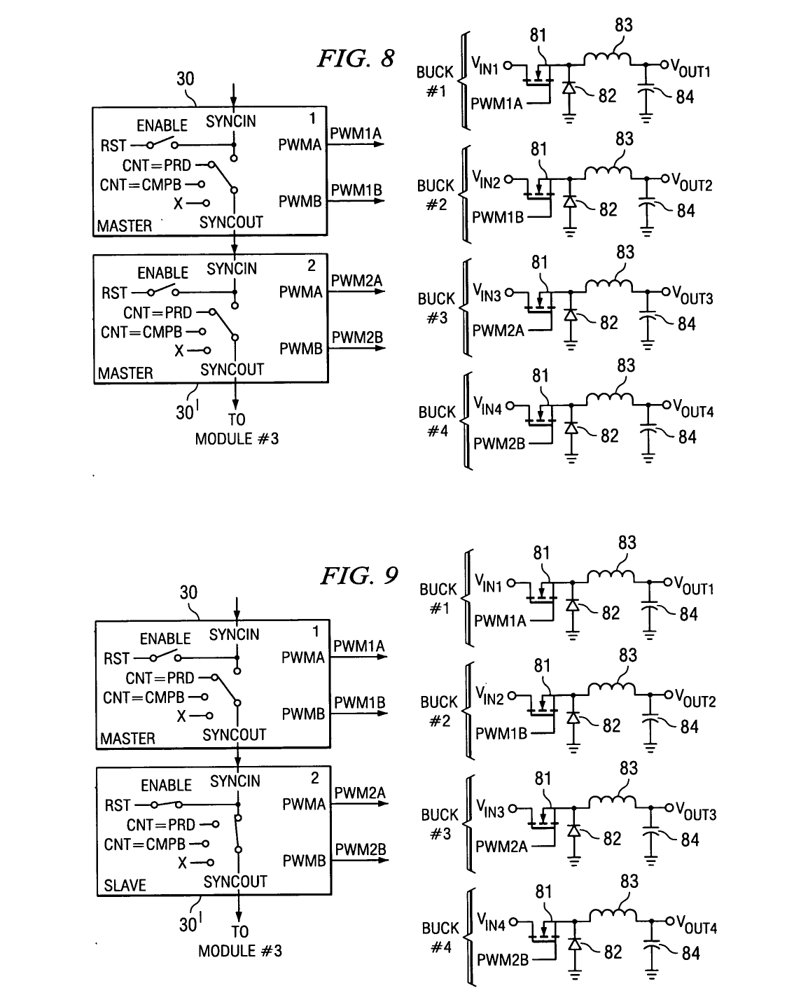

When synchronization is required between the first two and the second two buck stages, the second PWM module can be configured to be in the “slave” mode. This configuration is shown in FIG. 9, the difference for FIG. 8 being the second PWM module is configured in the “slave” mode. Because of the “master”/“slave” relationship, the second PWM module receives the synchronization signals from the “master” module.

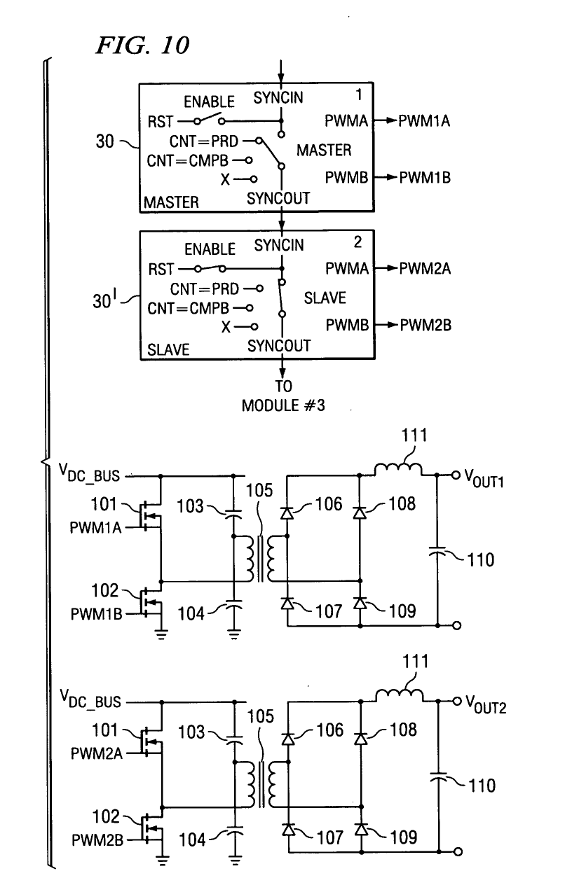

Configurations that require control of multiple switching elements can be addressed with the same PWM modules. Referring to FIG. 10, a single module is shown controlling a Half-H bridge stage 10. The Half-H stage 10 includes a VDC-BUS coupled to a first current terminal of FET transistor 101 and to a first terminal of capacitor 103. A second current terminal of FET transistor 101 is coupled to a first input terminal of transformer 105 and to a first current terminal of FET transistor 102. The second current terminal of transistor 102 is coupled to the ground potential. A second terminal of capacitor 103 is coupled to a second input terminal of transformer 105 and is coupled through capacitor 104 to the ground potential. A first output terminal of transformer 105 is coupled to an anode terminal of diode 106 and to a cathode terminal of diode 107. The cathode terminal of diode 106 is coupled to a cathode terminal of diode 108 and through inductor 111 to the Vout1 terminal and to a first terminal of capacitor 110. The anode terminal of diode 107 is coupled to the cathode terminal of diode 109 and to a second terminal of capacitor 110. A second output terminal of transformer 105 is coupled to an anode terminal of diode 108 and to a cathode terminal of diode 109. The control terminal of FET transistor 101 has the PMW1A applied thereto, while the control terminal of FET transistor has the FWM1B signal applied thereto. The module 1, acting in the “master” mode provides the PWM1A signals and the PWM2A signals. The second PMW module 2, acting in the “slave” mode provides PWM2A and PMW2B signals to the second Half-H bridge stage that is a multiple of the frequency provided by the first PWM module.

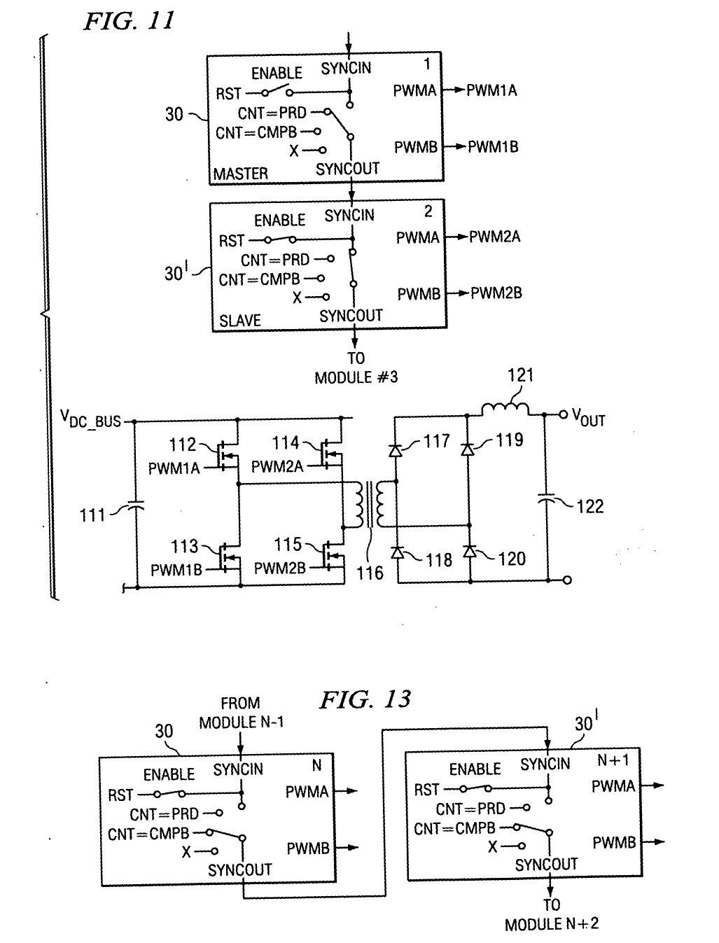

Referring to FIG. 11, the use of the modules of the present invention are to control a Full-H bridge stage is illustrated. A “master” PWM module provides the PWM1A and the PMW1B signals to the Full-H bridge state. In the Full-H bridge stage, the VDC-BUS is coupled to a first terminal of capacitor 111, to a first current terminal of FET transistor 112, and to a first current terminal of FET transistor 114. A common terminal is coupled to a second terminal of capacitor 111, to a first current terminal of FET transistor 113, and to a first current terminal of FET transistor 115. A second current terminal of FET transistor 112 is coupled to a second terminal of FET transistor 113 and to a first input terminal of transformer 116. A second current terminal of FET transistor 114 is coupled to a second current terminal of FET transistor 115 and to a second input terminal of transformer 116. The first output terminal of transformer 116 is coupled to a anode of diode 117 and to a cathode of diode 118. The second transformer output terminal is coupled to an anode of diode 119 and to a cathode of diode 120. The cathode of diode 117 is coupled to the cathode of diode 110 and through inductor 121 to a first terminal of capacitor 122 and to the VOUT terminal. The anode of diode 118 is coupled to the anode of diode 120, to a second terminal of capacitor 122, and to a common terminal. The “master” module provides a PWM1A signal to a control terminal of FET transistor 112 and a PWM1B signal to a control terminal of FET transistor 113. The “slave” PWM module provides a PWM2A signal to the control terminal of FET transistor 114 and a PWM2B signal to a control terminal of FET transistor 115. In this application, the frequencies of the signals provided by the “master” and the “slave” modules are synchronized.

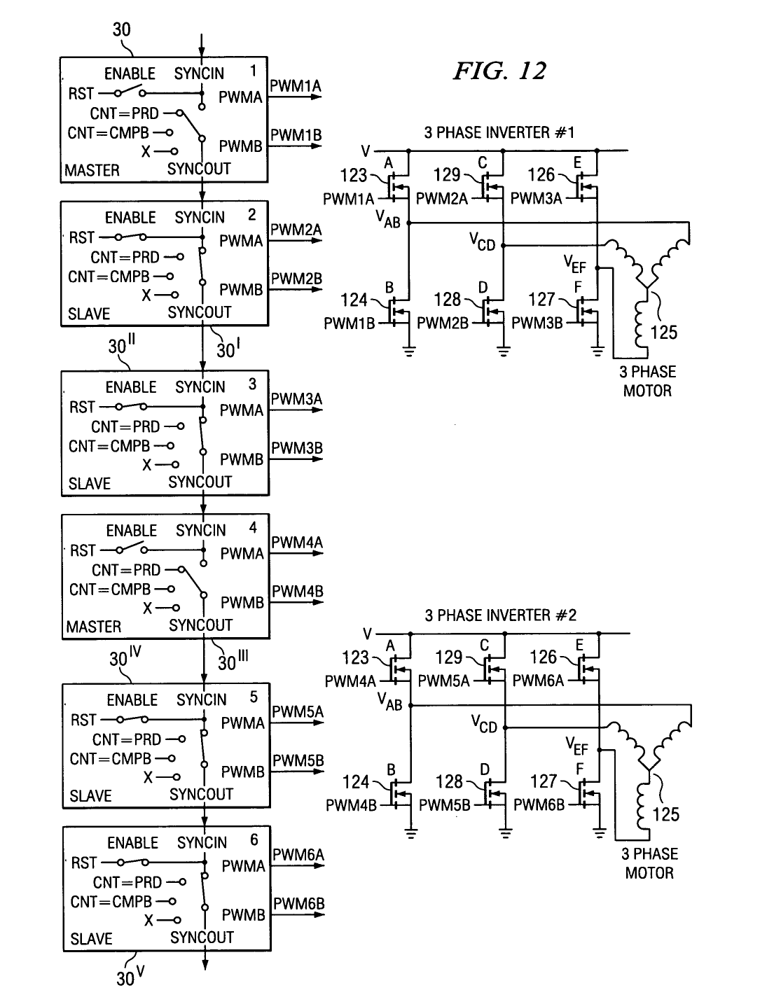

Referring to FIG. 12, the application of the modules of the present invention to the control of a 3-phase inverter motor is shown. In fact, FIG. 12 illustrates the control of two 3-phase inverter motors. 3-phase inverter motor 125 has the output of a first winding coupled to a first current terminal of FET transistor 123 and a first current terminal of FET transistor 123 and to a first current terminal of FET transistor 123. A second winding of 3-phase inverter motor 125 is coupled to a first current terminal of FET transistor 129 and to a first current terminal of FET transistor 128. A third winding of 3-phase inverter motor 125 is coupled to a first current terminal of FET transistor 126 and to a first current terminal of FET transistor 127. The second current terminal of FET transistor 124, the second current terminal of transistor 128 and a second current terminal of FET transistor 127 are coupled to ground potential. A second current terminal of FET transistor 123, a second current terminal of FET transistor 129, and a second current terminal of FET transistor 126 are coupled to the power voltage terminal Y. The PMW1A signal and the PWM1B signal from the “master” PWM module are applied to the control terminal of FET transistor 123 and to the control terminal of FET transistor 124, respectively.

In the applications of the PWM modules described above, the relationship of “slave” module PWM signals are determined by the contents of the counter register 11 (FIG. 3). The phase relationship between a “master” module and a “slave” module can also be controlled by the compare B register 32 (FIG. 1). This type of phase control is illustrated with the simplified module diagrams in FIG. 13. The SYNCOUT signal from the “master” module is generated from the compare B register 32. When applied to the “slave” module, this signal becomes the SYNCIN signal and, because the enable switch is closed, controls the signal generation of the “slave” module PWM signals.

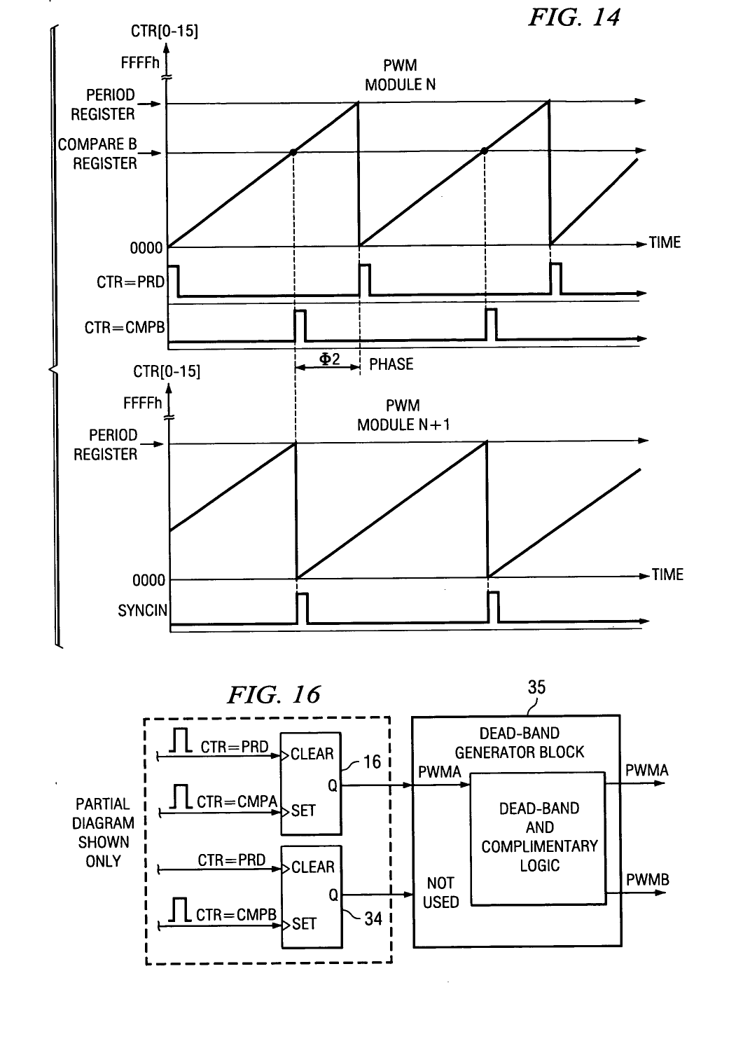

The control of the relationship of the PWM signals from the “master” and the “slave” modules by the “master” module compare B register is illustrated in FIG. 14. The SYNC signal from the master module resets the signals in the “slave” module.

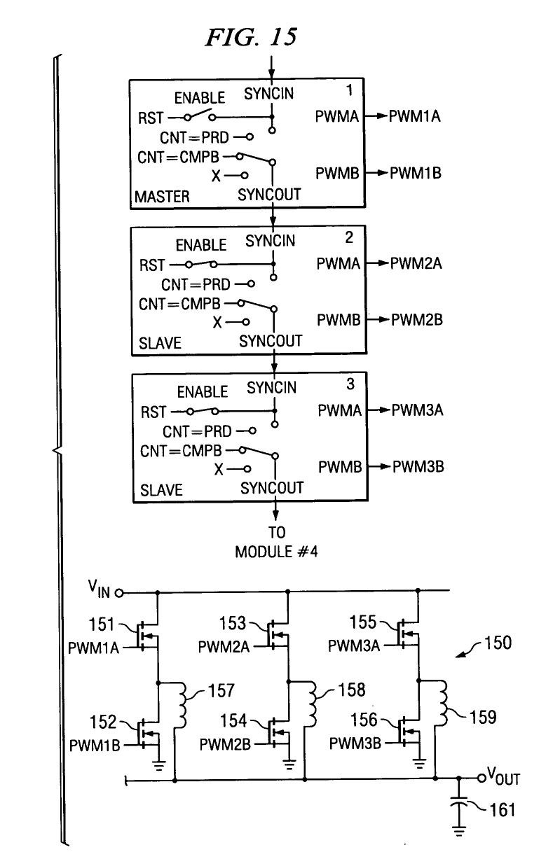

Referring to FIG. 15, the use of the PWM modules of the present invention to control the power provided to a DC/DC converter 150 is shown. In DC/DC converter 150, a first current terminal of FET transistor 151 is coupled to a first current terminal of FET transistor 152 and through inductor 157 to the Vout terminal. A first current terminal of FET transistor 153 is coupled to a first current terminal of FET transistor 154 and through inductor 158 to the Vout terminal. A first current terminal of FET transistor 155 is coupled to a first current terminal of transistor 156 and through inductor 159 to the Vout terminal. A second current terminal of FET transistor 152, a second current terminal of FET transistor 154, and a second current terminal of FET transistor 156 are coupled to ground potential. A second current terminal of FET transistor 151, a second current terminal of FET transistor 153, and a second current terminal of FET transistor 155 are coupled to the Vin terminal. Capacitor 161 is coupled between the Vout terminal and ground. The “master” module applies a PWM1A signal to the control grid of the FET transistor 151 and a PWM1B signal to the control terminal of FET transistor 152. The second (and “slave”) FWM module applies an PWM2A signal to the control terminal of FFT transistor 153 and an PWM2B signal for the control terminal of FET transistor 153. The third (and “slave”) FWM module applies a PWM3A signal to a control terminal of FET transistor 155 and an FWM3B signal for a control terminal FET transistor 156. The reset in the “slave” modules is the result of the count in the compare register B of the previous FWM module. In the example of DC/DC converter, the phases of the FWM signals from the modules must be 1200 out of phase. This phase relationship is accomplished when the count in the compare register B is on third of the count in the counter register in the “master” module.

In the block diagram of the PWM module shown in FIG. 3, a PWM module includes a dead band logic unit 35. Referring to FIG. 16, the generation of the two output signals from the PMW module is actually the result of a single output signal from Q flip-flop 16 applied to dead band logic unit 35. The signal from the Q flip-flop 34 is not applied to the dead band logic unit 35 and the two output signals are generated by the dead band logic unit 35. This is a result of the two signals being complementary.

2. Operation of the Preferred Embodiment

The present invention provides a plurality of PWM modules, typically coupled in series that can have programmable relationship between the PWM signals of two modules. Each module generates two PWM signals. The two PWM signals have same period but different duty cycles. Each PWM module can be programmed to be reset by an internal signal related to the first PWM signal reset signal or by an external signal. Each PWM module can supply the externally applied signal, a first PWM reset signal, or a second PWM set signal. The ability to respond to external signals permits a master module to control the relationship of the PWM signals of a second module.

The present invention is intended to be used as a component in an integrated circuit; all of the configurations that have been described can be made programmable under control of the microprocessor or the digital signal processor. When multiple instances of the PWM module are integrated on a chip, a flexible PWM system can be provided. Theoretically, any number of PWM modules can be included in a system. Although the electrical coupling between the modules is fixed, the inter-module synchronization scheme offers the flexibility to address almost all switched power configurations requiring PWM signaling and/or combinations of independent configurations on a signal chip.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. In an integrated circuit, a PWM module, the module comprising:
a first circuit, the first circuit generating a first pulse width modulated signal having a first period; and
a second circuit, the second circuit generating a second pulse width modulated signal having the first period and a duty cycle independent of the first pulse width modulated signal.

2. The module as recited in claim 1, including programmable switch, the programmable switch selecting a reset signal to be applied to the first circuit.

3. The module as recited in claim 2, wherein the integrated circuit includes a plurality of modules, the module further including gate apparatus for programmably applying the reset signal to a second module.

4. The module as recited in claim 3, wherein the second module receives the first module synchronization signal.

5. The module as recited in claim 2, wherein the integrated circuit includes a plurality of modules, the module further including gate apparatus for programmably applying a set signal for the second pulse width modulated signal.

6. The module as recited in claim 1, wherein the second circuit includes a first compare register and a second compare register.

7. The module as recited in claim 1, wherein the first circuit includes:
a counter for counting system clock signals;
a period register having number stored therein; and
a comparator, the comparator comparing a number in the counter with the number stored in the period register, the comparator providing the reset signal when the number in the counter and the number in the period register are equal.

8. The module as recited in the claim 1, wherein the module has a master mode and a slave mode, the operation of a slave mode module being synchronized with the operation of an associated master mode module.

9. The module as recited in claim 1, further including a dead band logic unit, the dead band logic unit having at least one of the first pulse width modulated signal and the second pulse width modulated signal.

10. A method of providing pulse width modulated signals, the method comprising:
in a PWM module, generating a first pulse width modulated signal with a first period and a first duty cycle; and
in the PWM module, generating a second pulse width modulation signal having the first period and a second duty cycle.

11. The method as recited in claim 10 further comprising:
operating the PWM module in a master mode, a master mode PWM module operating independently; and
operating the PWM module in a slave mode, the operation of a slave mode PWM module determined by control signals from a second PWM module.

12. The method as recited in claim 11, wherein the slave module receives the master module synchronization signal.

13. The method as recited in claim 11 further comprising resetting the PWM module by an external signal.

14. The method as recited in claim 11 further comprising providing a SYNCOUT signal from a PWM signal from the group consisting a signal applied to the PWM module, a reset signal for the first pulse width modulated signal, and a set signal for the second pulse width modulated signal.

15. The method a recited in claim 10 further comprising, in at least one PWM module, providing power to a component selected from the group consisting of a 3-phase inverter, at least one Buck stage, a DC/DC converter, and at least one Half-H bridge stage.

16. An integrated circuit, the circuit comprising;
integrated circuit components, the integrated circuit components including a plurality of programmable PWM modules coupled in series, the PWM modules providing power to selected integrated circuit components, each PWM module including:
a first circuit for providing a first PWM signal having a first period and having a first duty cycle; and
a second circuit for providing a second PWM signal having the first period and having a second duty cycle.

17. The circuit as recited in claim 16, wherein the PWM module further includes a programmable switch, the programmable switch selecting a reset signal to be applied to the first circuit.

18. The circuit as recited in claim 16, each PWM module includes programmable gate, the programmable gate selecting a reset signal to be applied to a next sequential PWM module.

19. The circuit as recited in claim 16, wherein the PWM module can operate in a master mode and in a slave mode.

20. The circuit as recited in a claim 16, wherein the selected integrated circuit components are selected from the group consisting of: a 3-phase inverter, at least one Buck stage, a DC/DC converter, and at least one Half-H bridge stage.

21. The circuit as recited in claim 18, wherein the reset signal applied to the next sequential PWM module is selected from the group consisting of: an external signal applied to the PWM module, a reset signal from the first circuit, and a set signal from the second circuit.

22. The circuit as recited in claim 19, wherein a module in the master mode applies an internal synchronization signal to a module in the slave mode.
